(19) United States
(12) Patent Application Publication
(10) Pub. No.: US 2026/0118381 A1
(43) Pub. Date: Apr. 30, 2026

(54) ELECTRICAL CONNECTION DEVICE

(71) Applicant: Kabushiki Kaisha Nihon Micronics, Tokyo (JP)

(72) Inventors: Kaori SANO, Oita (JP); Kazunori Ninomiya, Oita (JP); Shigeru Kinoshita, Oita (JP); Naofumi Kida, Oita (JP); Mizuho Kon, Oita (JP)

(73) Assignee: Kabushiki Kaisha Nihon Micronics, Tokyo (JP)

(21) Appl. No.: 19/348,841

(22) Filed: Oct. 3, 2025

(30) Foreign Application Priority Data
Oct. 30, 2024 (JP) 2024-190922

(51) Int. Cl. G01R 1/067; G01R 31/28

(52) U.S. Cl. CPC G01R 1/06755; G01R 31/2886

(57) ABSTRACT

An electrical connection device includes: a first substrate having a first surface and a second surface facing in a direction opposite to the first surface; a fixing nut that is disposed in an interior of the first substrate; a second substrate that is laminated on the second surface; and a fixing bolt disposed on the second substrate. A threaded portion of the fixing bolt is inserted into the first substrate from the second surface by passing through at least a portion of the second substrate, and the first substrate is fixed to the second substrate by engaging the threaded portion of the fixing bolt with the fixing nut.

### CROSS-REFERENCE TO RELATED APPLICATION

The present application is based on, and claims priority from Japanese Patent Application No. 2024-190922, filed on Oct. 30, 2024, the entire contents of which are incorporated herein by reference.

### TECHNICAL FIELD

The present disclosure relates to an electrical connection device that is used for inspecting the electrical characteristics of an inspection object.

### BACKGROUND

In order to measure the electrical characteristics of an inspection object such as an integrated circuit, an electrical connection device that electrically connects an inspection object and an inspection device has been used. The electrical connection device includes, as components, a probe to be brought into contact with the inspection object, a probe head that supports the probe, and a wiring substrate on which internal wiring for electrically connecting the probe and the inspection device is disposed.

The wiring substrate includes internal wiring such as signal wiring for propagating electrical signals between the signal terminal of the inspection object and the inspection device, ground wiring for supplying ground voltage to the inspection object, and power supply wiring for supplying power supply voltage to the inspection object. A probe pad that connects to the internal wiring is disposed on the surface of the wiring substrate. By laminating the probe head and the wiring substrate, the probe comes into contact with the probe pad, and thus the probe electrically connects to the internal wiring of the wiring substrate.

### SUMMARY

The probe head is fixed to the wiring substrate by, for example, a fixing screw inserted from the lower surface facing the inspection object. In this case, the fixing screw may loosen due to vibration or the like during the inspection of an inspection object. There is a concern that the loose fixing screw may protrude from the lower surface of the probe head and come into contact with the inspection object, or the fixing screw may fall from the probe head onto the inspection object, thereby damaging the inspection object.

In view of the above problems, an object of the present application is to provide an electrical connection device that prevents an inspection object from being damaged by screws that fix the components of the electrical connection device.

An electrical connection device according to an embodiment includes: a first substrate having a first surface and a second surface facing in a direction opposite to the first surface; a fixing nut that is disposed in an interior of the first substrate; a second substrate that is laminated on the second surface; and a fixing bolt disposed on the second substrate. A threaded portion of the fixing bolt is inserted into the first substrate from the second surface by passing through at least a portion of the second substrate, and the first substrate is fixed to the second substrate by engaging the threaded portion of the fixing bolt with the fixing nut.

The present application makes it possible to provide an electrical connection device that prevents an inspection object from being damaged by screws that fix the components of the electrical connection device.

### BRIEF DESCRIPTION OF THE DRAWINGS

FIG. 1 is a schematic view illustrating the structure of an electrical connection device according to an embodiment.

FIG. 2 is a schematic enlarged view illustrating a structure of a fixing nut and a fixing bolt of the electrical connection device according to the embodiment.

FIG. 3 is a schematic enlarged view illustrating another structure of the fixing nut and the fixing bolt of the electrical connection device according to the embodiment.

FIG. 4 is a schematic top view illustrating the structure of the fixing nut of the electrical connection device according to the embodiment.

FIG. 5 is a schematic view illustrating the structure of the electrical connection device according to a comparative example.

FIG. 6 is a schematic view illustrating the structure of the electrical connection device according to a modified example of the embodiment.

### DETAILED DESCRIPTION

Next, an embodiment will be described with reference to the drawings. In the following description of the drawings, identical or similar parts are denoted by identical or similar reference numerals. However, it should be noted that the drawings are schematic, and the thickness ratios of each part differ from actual ones. It is also natural that portions with different dimensional relationships and ratios are included between the drawings. The embodiment shown below exemplifies devices and methods for embodying the technical concept of the present disclosure, and the embodiments do not limit the materials, shapes, structures, arrangements, and the like of the component parts to those described below.

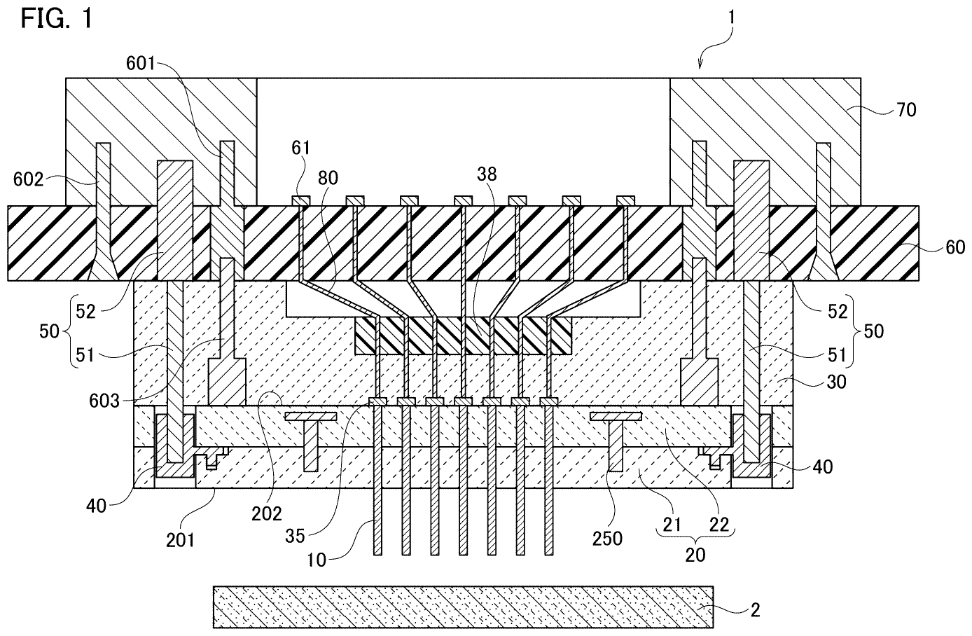

An electrical connection device 1, which is illustrated in FIG. 1, according to an embodiment is used for measuring the electrical characteristics of an inspection object 2. The electrical connection device 1 includes a first substrate 20 having a first surface 201 facing the inspection object 2 and a second surface 202 facing in a direction opposite to the first surface 201, and a second substrate 30 laminated on the second surface 202 of the first substrate 20. Further, the electrical connection device 1 includes fixing nuts 40 disposed in the interior of the first substrate 20 and fixing bolts 50 disposed on the second substrate 30. Each fixing bolt 50 has a threaded portion inserted into the first substrate 20 from the second surface 202 by passing through at least a portion of the second substrate 30. The threaded portion of each fixing bolt 50 engages with a corresponding fixing nut 40, and thus the first substrate 20 is fixed to the second substrate 30. The details of the fixing nuts 40 and the fixing bolts 50 will be described later.

In the description of the embodiment, the direction in which the second substrate 30 is positioned as seen from the first substrate 20 is referred to as the upward direction, and the direction in which the first substrate 20 is positioned as seen from the second substrate 30 is referred to as the downward direction. Further, the surface facing the upward direction is referred to as the upper surface, and the surface facing the downward direction is referred to as the lower surface. For example, the first surface 201 is the lower surface of the first substrate 20, and the second surface 202 is the upper surface of the first substrate 20. Moreover, the direction perpendicular to the up-down direction is referred to as the horizontal direction. The first surface 201 and the second surface 202 extend in the horizontal direction.

Each probe 10 includes a signal probe that propagates electric signals between the inspection object 2 and the inspection device, and a power source probe that supplies a power supply voltage or a ground voltage to the inspection object 2. Each probe 10 has a tip portion which is one end in contact with a terminal (not illustrated) of the inspection object 2, and a base end which is the other end. Each probe 10 may be made of nickel (Ni) or nickel alloy, for example.

The first substrate 20 may be a probe head that holds probes 10 in such a way as to extend from the first surface 201 toward the inspection object 2. The first substrate 20 is formed with a guide hole penetrating from the first surface 201 to the second surface 202 facing in the direction opposite to the first surface 201. The first substrate 20 supports the probes 10 passing through the guide hole. The first substrate 20 is made of ceramic, for example.

The second substrate 30 may be a wiring substrate having internal wirings electrically connected to the probes 10. Probe pads 35 are disposed on the lower surface of the second substrate 30 facing the first substrate 20. The base end of each probe 10 penetrating the first substrate 20 is in contact with a corresponding probe pad 35 that is electrically connected to the internal wiring. The second substrate 30 may be a multilayer wiring substrate such as an MLO (Multi-Layer Organic) substrate or an MLC (Multi-Layer Ceramic) substrate. Each probe pad 35 may be a metal material such as gold (Au) or copper (Cu).

The first substrate 20 of the electrical connection device 1 illustrated in FIG. 1 includes a first layer 21 having the first surface 201 and a second layer 22 having the second surface 202. The first layer 21 and the second layer 22 are laminated and fixed to each other by bonding pins 250.

The electrical connection device 1 further includes a printed substrate 60 and a stiffener 70 that are laminated in sequence on the second substrate 30.

The printed substrate 60 is disposed on the upper surface of the second substrate 30. A recess is formed in a portion of the upper surface of the second substrate 30 facing the lower surface of the printed substrate 60, and a space is provided in a portion of the area between the second substrate 30 and the printed substrate 60. The electrical connection device 1 includes wiring lines 80 that penetrates the second substrate 30 and the printed substrate 60 and passes through the space between the second substrate 30 and the printed substrate 60. One terminal of each wiring line 80 is electrically connected to a corresponding probe pad 35. The other terminal of each wiring line 80 is electrically connected to a corresponding electrode terminal 61 disposed on the upper surface of the printed substrate 60. In other words, one portion of each wiring line 80 is the internal wiring of the second substrate 30, and the other portion of each wiring line 80 is the printed wiring of the printed substrate 60 that is electrically connected to the internal wiring of the second substrate 30. Electrode terminals 61 of the printed substrate 60 are electrically connected to an inspection device such as a multimeter, which is not illustrated. Thus, the probes 10 and the inspection device are electrically connected to each other via the second substrate 30 and the printed substrate 60.

As described above, the wiring lines 80 pass through the recess formed in the upper surface of the second substrate 30. The wiring lines 80 may be fixed to the second substrate 30 by curing a fixing resin 38 poured into the recess.

The second substrate 30 may be, for example, a space transformer that makes the spacing between the wiring lines 80 wider than the spacing between the probes 10. The second substrate 30 may be, for example, a ceramic substrate or an MLO substrate.

The printed substrate 60 is fixed to a stiffener 70, which has higher rigidity than the printed substrate 60. The stiffener 70 ensures the mechanical strength of the electrical connection device 1 by preventing the printed substrate 60 from flexing, and is also used as a support body that fixes each of the component parts of the electrical connection device 1.

The printed substrate 60 is fixed to the rigid stiffener 70 by first connection screws 601 and second connection screws 602 that penetrate the printed substrate 60 from the lower surface to the upper surface. Further, the second substrate 30 is fixed to the printed substrate 60 by third connection screws 603 that penetrate the second substrate 30 from the lower surface to the upper surface. As illustrated in FIG. 1, tips of the third connection screws 603 may be joined to the head of the first connection screws 601.

The details of the fixing nuts 40 and the fixing bolts 50 will be described below.

As illustrated in FIG. 1, the fixing bolts 50 penetrate both the second substrate 30 and the printed substrate 60. An outer diameter of a second portion 52 of each fixing bolt 50 that penetrates the printed substrate 60 is larger than an outer diameter of a first portion 51 of each fixing bolt 50 that penetrates the second substrate 30. An end surface of the second portion 52 that protrudes more outwardly than an outer edge of the first portion 51 abuts against an upper surface of the second substrate 30 at the boundary between the first portion 51 and the second portion 52. Moreover, a part of the second portion 52 of each fixing bolt 50 that is exposed from the printed substrate 60 is housed in a hole formed in a lower surface of the stiffener 70.

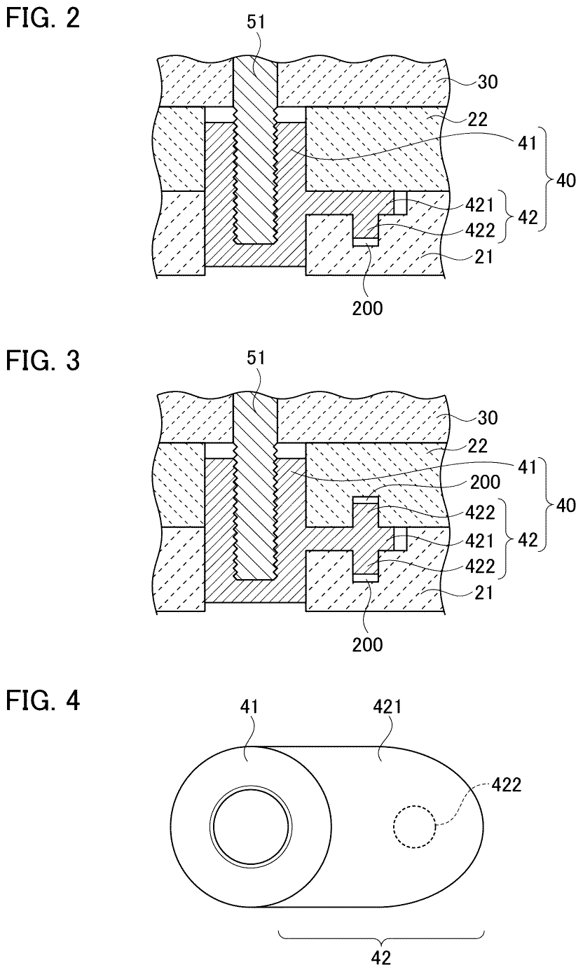

FIG. 2 illustrates an enlarged view of a portion where the fixing nut 40 and the fixing bolt 50 engage with each other. The fixing nut 40 includes a groove forming portion 41 in which a groove corresponding to the spiral groove formed on the side face of the threaded portion of the fixing bolt 50 is formed, and a flange portion 42 that is connected to the groove forming portion 41 and extends in a direction intersecting the extending direction (up-down direction) of the fixing bolt 50. The flange portion 42 illustrated in FIG. 2 extends horizontally, perpendicular to the up-down direction.

The flange portion 42 is fitted into the first substrate 20, and thus the fixing nut 40 is fixed to the first substrate 20. For example, as illustrated in FIG. 2, the flange portion 42 may be inserted into the space that is formed between the first layer 21 and the second layer 22. Thus, the flange portion 42 is fitted into the first substrate 20, which prevents the fixing nut 40 from falling from the first substrate 20. Moreover, it is possible to suppress idle rotation during screw tightening when the fixing bolt 50 engages with the fixing nut 40.

The flange portion 42 may include an insertion portion 421 that extends parallel to the first surface 201 and is inserted into the first substrate 20, and a protruding portion 422 that is disposed on the surface of the insertion portion 421 and protrudes in a direction intersecting an extending direction of the insertion portion 421. The protruding portion 422 protrudes in the up-down direction from the surface of the insertion portion 421, for example. A recessed portion 200 into which the protruding portion 422 fits is formed in the first substrate 20.

FIG. 2 exemplifies a case where the protruding portion 422 is formed on a lower surface of the insertion portion 421. Therefore, the recessed portion 200 is formed in the first layer 21. Meanwhile, when the protruding portion 422 is formed on an upper surface of the insertion portion 421, the recessed portion 200 is formed in the second layer 22. Further, as illustrated in FIG. 3, the protruding portion 422 may be formed on both the upper surface and the lower surface of the insertion portion 421. In this case, the recessed portion 200 is formed in both the first layer 21 and the second layer 22. Thus, the recessed portion 200 is formed in at least one of the first layer 21 and the second layer 22.

As described above, the protruding portion 422 of the flange portion 42 is fitted into the recessed portion 200 of the first substrate 20, and thus the fixing nut 40 is stably positioned on the first substrate 20. This prevents contact damage between the fixing nut 40 and the first substrate 20 that may be caused by impact during screw fastening when the fixing bolt 50 engages with the fixing nut 40.

The fixing nut 40 and the fixing bolt 50 do not protrude toward the inspection object 2 beyond the first surface 201. In other words, the entire fixing nut 40 and the threaded portion of the fixing bolt 50 are housed in the interior of the first substrate 20. This prevents the fixing nut 40 or the fixing bolt 50 from coming into contact with the inspection object 2.

Although not illustrated, the space in the first substrate 20 that is formed to fit the flange portion 42 therein may have a curved corner on the inner wall surface. This is because the space provided in the first substrate 20 is formed by drill machining. Therefore, as illustrated in FIG. 4, the corner of the insertion portion 421 may be R-chamfered. FIG. 4 illustrates a top view of the fixing nut 40. Thus, by making the outer edge of the insertion portion 421 rounded, the side surface of the flange portion 42 and the inner wall surface of the space formed in the first substrate 20 are in surface contact with each other. This suppresses damage of the first substrate 20 due to contact between the first substrate 20 and the flange portion 42. Here, a certain space may be provided around the fixing nut 40 in consideration of the manufacturing margin of the electrical connection device 1. However, the narrower the clearance around the flange portion 42, the less rattling will occur, thereby suppressing inclination of the fixing nut 40 during screw tightening.

Although the fixing nut 40 in which one flange portion 42 extends from the groove forming portion 41 has been described above, the fixing nut 40 may have a plurality of flange portions 42 extending in respective different directions. For example, the fixing nut 40 may have two flange portions 42 extending in opposite directions. Although a description has been given of the case in which the flange portion 42 extends from the groove forming portion 41 in one direction, the flange portion 42 may extend in a plurality of directions. The fixing nut 40 can be fixed to the first substrate 20 more stably as the number of the flange portions 42 or the directions in which they extend increases. Meanwhile, by disposing the flange portion 42 only on one side of the groove forming portion 41, it is possible to suppress the increase in the area of the first substrate 20 and the second substrate 30.

Further, although a description has been given of the case in which the protruding portion 422 has a cylindrical shape, the shape of the protruding portion 422 is not limited thereto. Here, the protruding portion 422 and the insertion portion 421 may be integrally molded, or the protruding portion 422 made of a material different from the insertion portion 421 may be formed in the insertion portion 421.

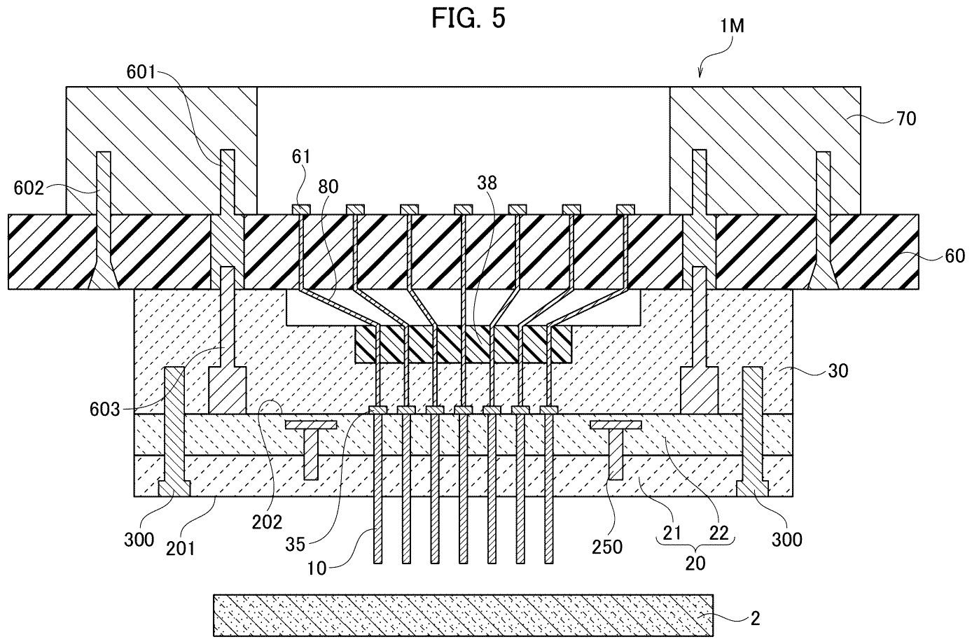

As described above, in the electrical connection device 1 according to the embodiment, the fixing bolts 50 that pass through at least a portion of the second substrate 30 engage with the fixing nuts 40 that are disposed in the interior of the first substrate 20, and thus the first substrate 20 is fixed to the second substrate 30. In contrast, in an electrical connection device 1M of a comparative example illustrated in FIG. 5, for example, the first substrate 20 is fixed to the second substrate 30 by fixing screws 300 inserted from the lower surface of the first substrate 20. Therefore, there is a risk that the fixing screws 300 protrude to the lower surface of the first substrate 20 and comes into contact with the inspection object or falls from the first substrate 20.

Meanwhile, according to the electrical connection device 1, even when the engagement between the fixing nut 40 and the fixing bolt 50 is loosened, the fixing nut 40 or the fixing bolt 50 does not protrude from the lower surface of the first substrate 20 or fall from the first substrate 20. Moreover, since the protruding portion 422 of the flange portion 42 is fitted into the recessed portion 200 of the first substrate 20, it is possible to suppress idle rotation during screw tightening when the fixing bolt 50 engages with the fixing nut 40, and contact damage between the fixing nut 40 and the first substrate 20.

Moreover, according to the electrical connection device 1, the first substrate 20 is fixed to the second substrate 30 by interposing the first substrate 20 and the second substrate 30 using the fixing nuts 40 and the fixing bolts 50. Therefore, even when the material of the first substrate 20 is not suitable for forming the screw groove, the first substrate 20 and the second substrate 30 can be connected with each other. Furthermore, by connecting the first substrate 20 and the second substrate 30 with the fixing nuts 40 and the fixing bolts 50, the first substrate 20 and the second substrate 30 can be easily separated from each other, which facilitates the maintenance such as replacement of parts of the electrical connection device 1, for example.

### MODIFIED EXAMPLE

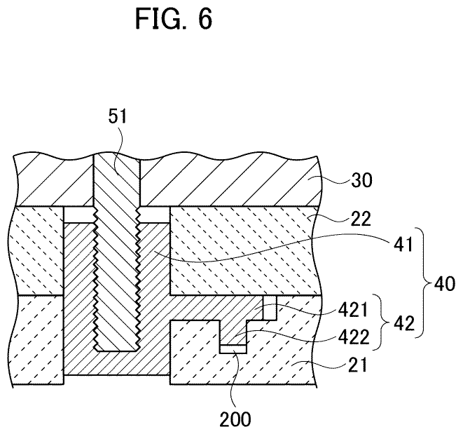

As illustrated in FIG. 6, the portion of the second substrate 30 where the fixing bolt 50 is disposed may be made of a conductive material that has higher rigidity than an insulating material such as ceramic. For example, the portion of the second substrate 30 where the internal wiring is disposed may be made of ceramic, and the outer edge portion where the fixing bolt 50 is disposed may be made of metal.

### Other Embodiments

The embodiment of the present invention has been described above, but the statements and drawings forming part of this disclosure should not be understood as limiting the invention. Various alternative embodiments, examples, and operating techniques will be apparent to those skilled in the art from this disclosure.

For example, although a description has been given of the case in which the first substrate 20 is made of ceramic, it may alternatively be made of other materials such as resin or glass. Alternatively, the first substrate 20 may be a thin metal plate in which screw grooves cannot be formed.

Further, the electrical connection device 1 may hold the probes 10 that are in curved states. By holding the probes 10 that are in curved states, when the tip portion of each probe 10 comes into contact with the inspection object 2, the probes 10 are further curved due to deflection deformation, and thus the probes 10 can be brought into contact with the inspection object 2 at a predetermined pressure. For example, the probes 10 can be curved in a space provided between the guide hole of the first layer 21 and the second layer 22 by an offset arrangement in which the guide hole of the first layer 21 and the guide hole of the second layer 22 of the first substrate 20 which the same probe 10 penetrates are shifted in the horizontal direction.

It should be understood that the present invention includes various embodiments not described herein. Therefore, the technical scope of the present invention is defined only by the invention-specifying matters according to the claims reasonably derived from the above description.

1. An electrical connection device used for inspecting an inspection object, comprising:
a first substrate having a first surface facing the inspection object and a second surface facing in a direction opposite to the first surface;
a fixing nut that is disposed in an interior of the first substrate;
a second substrate that is laminated on the second surface; and
a fixing bolt having a threaded portion inserted into the first substrate from the second surface by passing through at least a portion of the second substrate, and fixing the first substrate to the second substrate by engaging the threaded portion with the fixing nut.

2. The electrical connection device according to claim 1, wherein
the fixing nut comprises:
a groove forming portion in which a groove corresponding to a groove formed in the threaded portion of the fixing bolt is formed; and
a flange portion that is connected to the groove forming portion and extends in a direction intersecting an extending direction of the fixing bolt, and
the fixing nut is fixed to the first substrate by fitting the flange portion into the first substrate.

3. The electrical connection device according to claim 2, wherein
the flange portion comprises:
an insertion portion that extends parallel to the first surface and is inserted into the first substrate; and
a protruding portion that is disposed on a surface of the insertion portion and protrudes in a direction intersecting an extending direction of the insertion portion, and
a recessed portion into which the protruding portion fits is formed in the first substrate.

4. The electrical connection device according to claim 3, wherein
the first substrate comprises:
a first layer having the first surface; and
a second layer having the second surface,
the flange portion is inserted into a space that is formed between the first layer and the second layer, and
the recessed portion is formed in at least one of the first layer and the second layer.

5. The electrical connection device according to claim 1, wherein
the fixing nut and the fixing bolt do not protrude toward the inspection object beyond the first surface.

6. The electrical connection device according to claim 1, wherein
the first substrate is made of ceramic.

7. The electrical connection device according to claim 1, further comprising a probe in contact with the inspection object, wherein
the first substrate is a probe head that holds the probe in such a way as to extend from the first surface toward the inspection object.

8. The electrical connection device according to claim 7, wherein
the second substrate is a wiring substrate having internal wiring that is electrically connected to the probe.

9. The electrical connection device according to claim 8, further comprising
a printed substrate laminated on the second substrate, wherein
the fixing bolt penetrates both the second substrate and the printed substrate,
an outer diameter of a second portion of the fixing bolt that penetrates the printed circuit substrate is larger than an outer diameter of a first portion of the fixing bolt that penetrates the second substrate, and
an end surface of the second portion that protrudes more outwardly than an outer edge of the first portion abuts against the second substrate at a boundary between the first portion and the second portion.

10. The electrical connection device according to claim 9, further comprising
a rigid stiffener laminated on the printed substrate, wherein
a part of the second portion of the fixing bolt that is exposed from the printed substrate is housed in a hole formed in the stiffener.
